(19) United States
(12) Patent Application Publication
(10) Pub. No.: US 2012/0306484 A1
(43) Pub. Date: Dec. 6, 2012

(54) MAGNETIC DETECTION APPARATUS

(75) Inventors: Akitoshi Mizutani, Okazaki-city (JP); Naoaki Kouno, Chiryu-city (JP); Hitomi Honda, Kariya-city (JP); Tomoyuki Takiguchi, Okazaki-city (JP)

(73) Assignee: DENSO CORPORATION, Kariya-city (JP)

(21) Appl. No.: 13/460,876

(22) Filed: May 1, 2012

(30) Foreign Application Priority Data
Jun. 3, 2011 (JP) 2011-125465
Aug. 9, 2011 (JP) 2011-173830

(51) Int. Cl. G01R 33/02; B29C 45/14

(52) U.S. Cl. 324/244; 264/255

(57) ABSTRACT

A magnetic detection apparatus includes an IC device, a casing defining a housing space of the IC device, and a resin mold portion arranged on a first part of an outside surface of the casing. The IC device includes an IC package having a built-in magnetoelectric transducer, and lead wires. The housing space is defined by a second part of an inner wall of the casing. A predetermined portion of the second part of the inner wall is defined as a contact region, with which the IC device contacts. The resin mold portion is arranged other than a predetermined portion of a second part of the outside surface corresponding to the contact region. A position of the magnetoelectric transducer is determined by positions of the contact region and the resin mold portion.

### CROSS REFERENCE TO RELATED APPLICATIONS

This application is based on Japanese Patent Applications No. 2011-125465 filed on Jun. 3, 2011, and No. 2011-173830 filed on Aug. 9, 2011, the disclosures of which are incorporated herein by reference.

### TECHNICAL FIELD

The present disclosure relates to a magnetic detection apparatus having a magnetoelectric transducer such as a hall element.

### BACKGROUND

Conventionally, a magnetic detection apparatus having a magnetoelectric transducer such as a hall element is used for detecting a rotation angle or a linear displacement. As disclosed in JP-A-2004-004114 (which corresponds to U.S. Pat. No. 6,407,543), a magnetic detection apparatus includes an integrated circuit (IC) device molded with resin material by injection molding. The IC device includes an IC package that is placed inside of the IC device. In the IC package, a magnetoelectric transducer and processing circuits such as an amplification circuit are built in. A position of the magnetoelectric transducer is defined and stabilized by molding the IC device. When molding the IC device, an injection pressure caused by resin injection is applied to the IC package, which is placed inside the IC device. Thus, a characteristic of an output voltage of the IC device may have a voltage fluctuation.

Further, JP-A-2004-198240 (which corresponds to US 2004/0118227) discloses a detector. The detector is formed by molding a detection element in a casing, and then, molding the casing in a housing. In this patent document, a sensing portion functions as the detection element, a resin-molded sensor casing functions as the casing, and a resin-molded connector casing functions as the housing. The casing and the housing are made of thermoplastic resin, and formed by injection molding. Specifically, the casing is formed by a first molding. Then, the housing, which covers the casing, is formed by a second molding. Thus, the casing and the housing are integrated with each other by heat generated in the second molding. Therefore, no clearance is formed between the casing and the housing. This configuration can suppress moisture penetration to the detector.

However, when forming the casing by the first molding, an injection pressure caused by injection molding may be applied excessively to the detection element. Similarly, when forming the housing by the second molding, an injection pressure caused by injection molding may be applied excessively to the detection element through the casing. Thus, a reliability of an output voltage of the detector may be deteriorated.

### SUMMARY

In view of the foregoing difficulties, it is an object of the present disclosure to provide a magnetic detection apparatus in which a characteristic of an output voltage is less likely to fluctuate when defining a position of a magnetoelectric transducer by forming a resin mold portion in an injection molding manner. It is another object of the present disclosure to provide a detection apparatus in which an output reliability of a detection element is increased, and a manufacturing method of the detection apparatus.

According to a first aspect of the present disclosure, a magnetic detection apparatus includes an IC device, a casing, and a resin mold portion. The IC device includes an IC package having a built-in magnetoelectric transducer, and a plurality of lead wires extended from the IC package. The casing defines a housing space of the IC device. The resin mold portion is arranged on a first part of an outside surface of the casing. The first part of the outside surface of the casing corresponds to a first part of an inner wall of the casing. The housing space is defined by a second part of the inner wall of the casing. The second part of the inner wall of the casing corresponds to a second part of the outside surface of the casing. A predetermined portion of the second part of the inner wall of the casing is defined as a contact region, which is contacted with a predetermined part of an outside surface of the IC device. The resin mold portion is arranged other than a predetermined portion of the second part of the outside surface of the casing, which corresponds to the contact region. A position of the magnetoelectric transducer is determined by a position of the contact region, with which the IC package contacts, and a position of the resin mold portion.

In the above apparatus, when forming the resin mold portion by injection molding, an injection pressure caused by resin injection is not applied to the IC package of the IC device. Thus, when defining the position of the magnetoelectric transducer by forming the resin mold portion in an injection molding manner, a characteristic of an output voltage of the IC device is less likely to fluctuate.

According to a second aspect of the present disclosure, a detection apparatus includes a detection element, a casing, a plurality of terminals, a cover, and a housing. The detection element detects a physical quantity. The casing includes a bottom portion, and a cylindrical portion extending from an outer edge of the bottom portion in one direction. The casing houses the detection element inside of the cylindrical portion on a bottom portion side. A first end of each terminal couples with the detection element, and a second end of each terminal extends to an outside of the casing. The cover covers an opening portion of the cylindrical portion, and molds the plurality of terminals. The opening portion of the cylindrical portion is opposite to the bottom portion of the casing. The housing molds the cylindrical portion, the cover, and the plurality of terminals.

In the above apparatus, when forming the housing by injection molding, a penetration of the resin material of the housing to the cylindrical portion is suppressed by the cover. Thus, application of an injection pressure generated by the resin material of the housing is suppressed. Therefore, an output reliability of the detection element is increased.

According to a third aspect of the present disclosure, a manufacturing method of the detection apparatus, which is described in the second aspect of the present disclosure, includes forming the cover by a first injection molding of the plurality of terminals, which are inserted to the cover; coupling the plurality of terminals with the detection element; inserting the detection element in the casing after the forming of the cover and the coupling of the plurality of terminals with the detection element; covering the opening portion of the casing with the cover, which is inserted to the bottom portion side of the cylindrical portion of the casing; and forming the housing by a second injection molding of the cylindrical portion, the cover, and the plurality of terminals, which are inserted to the housing after the inserting of the detection element in the casing.

In the above method, an injection pressure generated in the first injection molding and an injection pressure generated in the second injection molding are less likely to apply to the detection element. Therefore, an output reliability of the detection element is increased.

### BRIEF DESCRIPTION OF THE DRAWINGS

The above and other objects, features and advantages of the present disclosure will become more apparent from the following detailed description made with reference to the accompanying drawings. In the drawings:

FIGS. 1A and 1B are diagrams respectively showing a plan view and a side view of a magnetic detection apparatus according to a first embodiment;

FIGS. 2A and 2B are diagrams respectively showing a cross-sectional plan view and a cross-sectional side view of the magnetic detection apparatus with a resin mold portion removed according to the first embodiment;

FIG. 3A is a diagram showing a cross-sectional plan view of a part of the magnetic detection apparatus according to the first embodiment, FIG. 3B is a diagram showing a cross-sectional view taken along line IIIB-IIIB in FIG. 3A, and FIG. 3C is a diagram showing a cross-sectional view taken along line IIIC-IIIC in FIG. 3B;

FIG. 4A is a diagram showing a cross-sectional plan view of a part of a magnetic detection apparatus according to a second embodiment, FIG. 4B is a diagram showing a cross-sectional view taken along line IVB-IVB in FIG. 4A, FIG. 4C is a diagram showing a side view seen from IVC in FIG. 4A, and FIG. 4D is a diagram showing an engagement between extension terminals and a lid;

FIG. 5A is a diagram showing a side view of a sub assembly of a magnetic detection apparatus according to a third embodiment, and FIG. 5B is a diagram showing a cross-sectional side view of the magnetic detection apparatus in FIG. 5A with a resin mold portion removed;

FIG. 6 is a diagram showing a cross-sectional view of a magnetic detection apparatus according to a fourth embodiment;

FIG. 7 is a diagram showing a cross-sectional view of a magnetic detection apparatus according to a fifth embodiment;

FIG. 8 is a diagram showing a cross-sectional view of a detection apparatus according to a sixth embodiment;

FIG. 9 is a diagram showing a perspective view of a manufacturing process of the detection apparatus according to the sixth embodiment;

FIG. 10 is a diagram showing a perspective view of a manufacturing process of the detection apparatus according to the sixth embodiment;

FIG. 11 is a diagram showing a perspective view of a manufacturing process of the detection apparatus according to the sixth embodiment;

FIG. 12 is a diagram showing a perspective view of a manufacturing process of the detection apparatus according to the sixth embodiment;

FIG. 13 is a diagram showing a perspective view of a manufacturing process of the detection apparatus according to the sixth embodiment;

FIG. 14 is a diagram showing a perspective view of the detection apparatus according to the sixth embodiment;

FIG. 15 is a flowchart showing a manufacturing process of the detection apparatus according to the sixth embodiment;

FIG. 16 is a diagram showing a cross-sectional view of a detection apparatus according to a seventh embodiment; and

FIG. 17 is a flowchart showing a manufacturing process of the detection apparatus according to the seventh embodiment.

### DETAILED DESCRIPTION

A magnetic detection apparatus according to a first embodiment includes an integrated circuit (IC) device, and a casing. The IC device has an IC package, in which a magnetoelectric transducer is built in, and lead wires extended from the IC package. Further, the casing has a resin mold portion formed on a first part of an outside surface of the casing by injection molding. The first part of the outside surface of the casing corresponds to a first part of an inner wall of the casing. An inner space of the casing is defined for housing the IC device by a second part of the inner wall of the casing. A predetermined portion of the second part of the inner wall of the casing contacts with a part of outside surface of the IC device, and is defined as a contact region. The resin mold portion is arranged other than a predetermined portion of the second part of the outside surface of the casing, which corresponds to the contact region. Under this configuration, a position of the magnetoelectric transducer is defined by contacting the IC package with the contact region, and forming the resin mold portion on the first part of the outside surface of the casing.

Further, the casing has a flange-shaped protruding portion on a predetermined portion of the first part of the outside surface of the casing. The protruding portion is formed around the housing space extending in a radially outside direction. The protruding portion is welded with the resin mold portion. The IC package is sandwiched by sub contact regions, which configure the contact region, to be maintained at a predetermined position. The magnetic detection apparatus further has extension terminals with which the respect lead wires of the IC device are electrically coupled. Between adjacent two extension terminals, a capacitor is mounted. The capacitor is sealed with potting material, which is injected to the housing space.

In a magnetic detection apparatus according to a second embodiment, the casing has an opening portion for housing the IC device in the housing space. The opening portion is covered by a lid, and the lid has through holes corresponding to the extension terminals. One of the extension terminals has a stopper to define a position of the lid. The lid is engaged with the one of the extension terminals by the stopper, and is integrated with the casing by thermal caulking. Thus, the opening portion of the casing is covered by the lid.

A magnetic detection apparatus according to a third embodiment includes a sub assembly having insert components. The insert components include the IC device other than the IC package, the extension terminals, and the capacitors, which are molded integrally by injection molding. The sub assembly is housed in the casing, and then, a resin mold portion is formed.

### First Embodiment

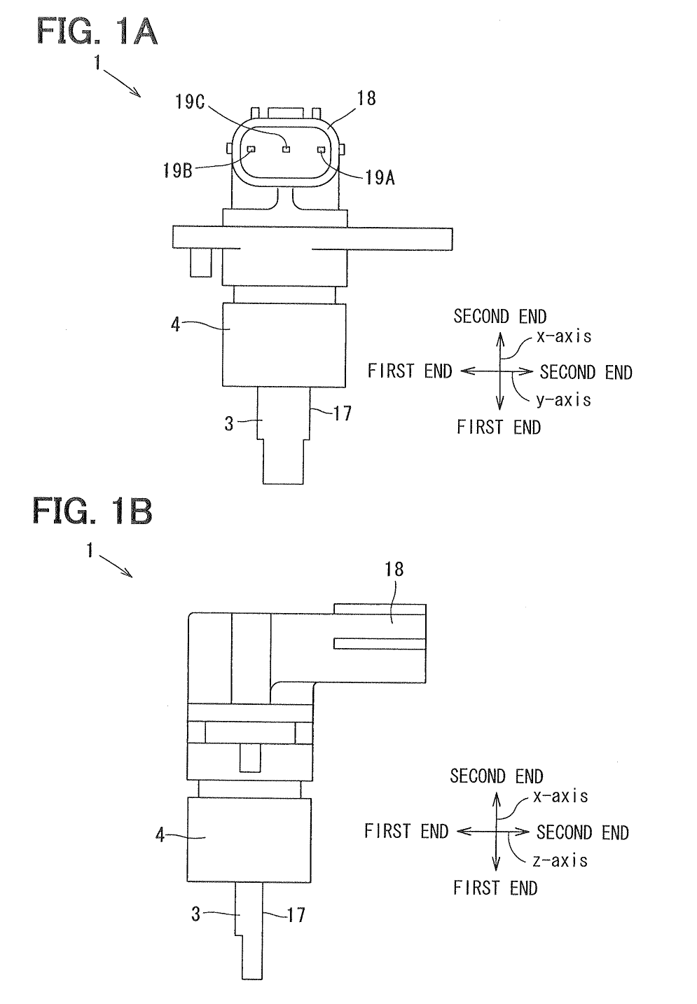

The magnetic detection apparatus 1 (hereinafter referred to as a detection apparatus) according to the first embodiment will be described with reference to FIGS. 1A to 3C. For example, the detection apparatus 1 includes a magnetoelectric transducer (not shown) such as a hall element, and a magnetic flux generator (not shown) such as a permanent magnet. When the magnetic flux generator rotates relatively around the magnetoelectric transducer or moves to have a linear displacement relative to the magnetoelectric transducer, a magnetic filed generated by the magnetic flux generator varies. The detection apparatus 1 detects a rotation angle or a linear displacement by combining the magnetic flux generator with the magnetoelectric transducer. That is, with a function of the magnetoelectric transducer, the detection apparatus detects a magnetic flux content corresponding to a rotation angle or linear displacement of the magnetic flux generator, and generates a voltage corresponding to the detected magnetic flux content.

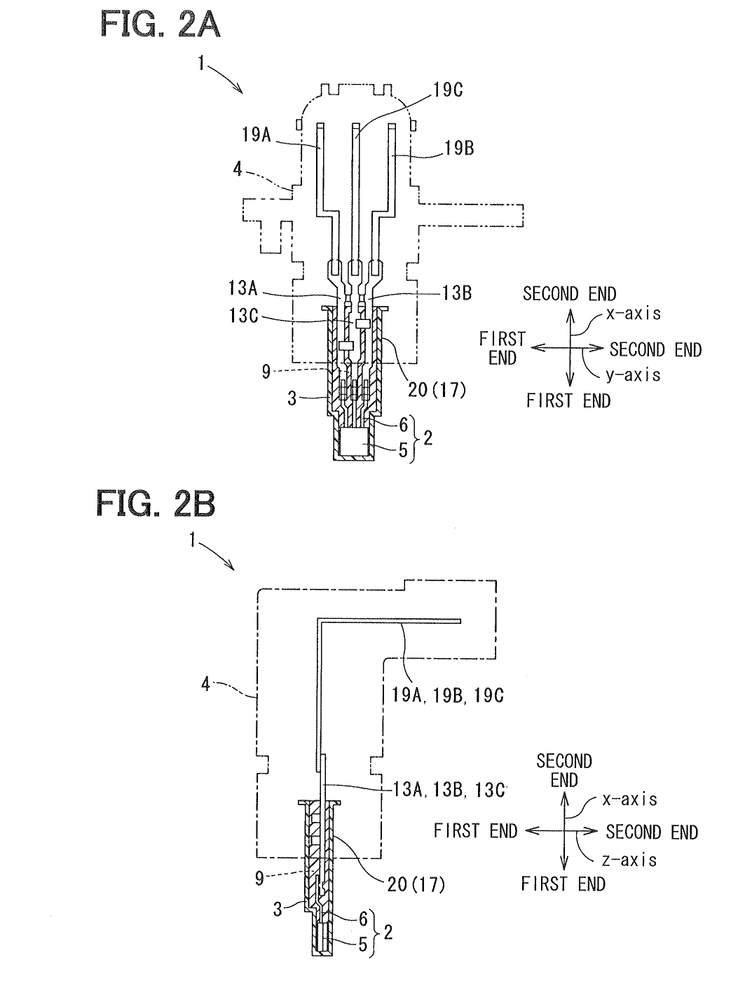

As shown in FIG. 2A, the detection apparatus 1 includes an IC device 2, a casing 3, and a resin mold portion 4. The IC device 2 includes a magnetoelectric transducer, and is housed in the casing 3. The resin mold portion 4 is formed on the first part of the outside surface of the casing 3 by injection molding. A position of the magnetoelectric transducer is defined by housing the IC device 2 in the casing 3, and forming the resin mold portion 4 on the first part of the outside surface of the casing 3. The first part of the outside surface of the casing 3 corresponds to a first part of the inner wall of the casing 3.

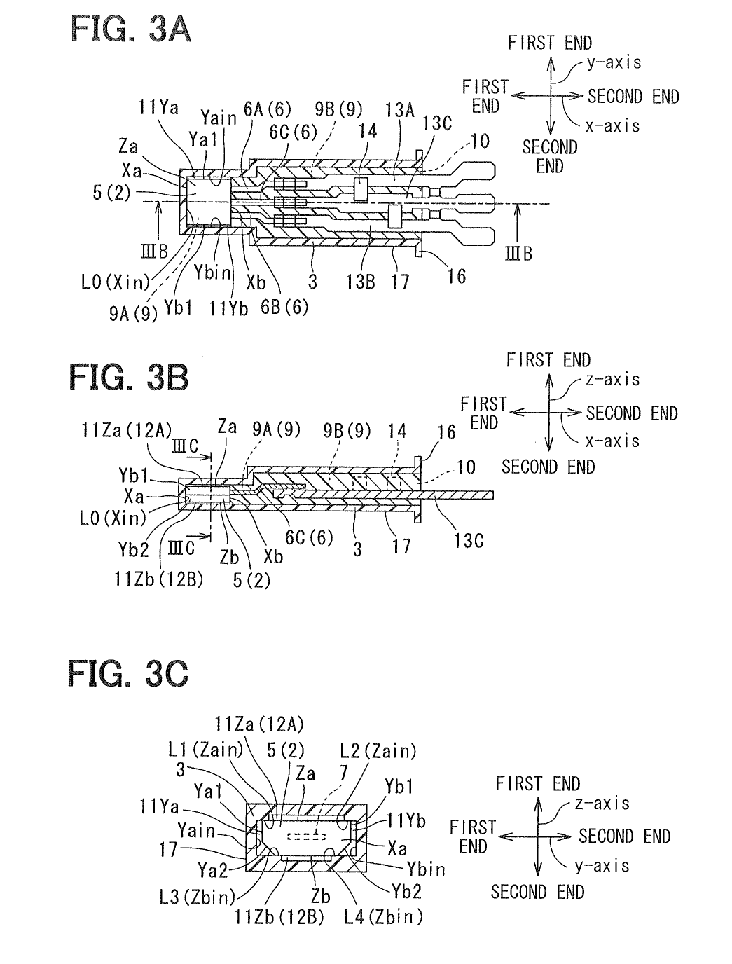

As shown in FIGS. 2A and 2B, the IC device 2 includes an IC package 5, in which the magnetoelectric transducer is built in, and lead wires 6 extended form the IC package 5. As shown in FIG. 3C, the IC package 5 is configured by molding a semiconductor substrate 7, on which the magnetoelectric transducer and other components are mounted, with a resin material such as an epoxy resin. The lead wires 6 are used for electrically coupling the components mounted on the semiconductor substrate 7 with external components (not shown).

The IC package 5 has an approximately same plane direction with the semiconductor substrate 7, and is approximately shaped in a square plate. The lead wires 6 are perpendicularly protruded from a side surface, which includes an end side of the square. Specifically, as shown in FIG. 3A, there are three lead wires 6 protruded from the IC package 5. The three lead wires 6 include a lead wire 6A for outputting a voltage generated by the magnetoelectric transducer, a lead wire 6B for providing a power supply (not shown) to the magnetoelectric transducer, and a lead wire 6C for electrically coupling the magnetoelectric transducer to the ground.

As shown in FIG. 3A, in the casing 3, a housing space 9 for the IC device 2 is defined by a second part of the inner wall of the casing 3. The second part of the inner wall of the casing 3 corresponds to a second part of the outside surface of the casing 3. The casing 3 is made of resin by injection molding. The housing space 9 includes a first housing space 9A for housing the IC package 5, and a second housing space 9B extended from the first housing space 9A. The first housing space 9A is placed at a front end side of the casing 3, and the second housing space 9B is extended to a tail end side of the casing 3 connected with the first housing space 9A. A front end side of the first housing space 9A is blocked by the casing 3. On a tail end side of the second housing space 9B, an opening portion 10 for housing the IC device 2 in the housing space 9 is defined by the casing 3.

A coordinate system is defined to describe a position state of the magnetoelectric transducer, which is built in the IC package 5, in the first housing space 9A. In the coordinate system, x-axis is defined in a direction from the front end side of the casing 3 to the tail end side of the casing 3; y-axis is defined in a direction perpendicular to the x-axis and parallel to a broad surface of the IC package 5; and z-axis is defined in a direction perpendicular to the x-axis and y-axis and perpendicularly penetrating the broad surface of the IC package 5. Further, a first and a second end sides of the x-axis, a first and a second end sides of the y-axis, and a first and a second end sides of the z-axis are defined as shown in FIGS. 2A to 3C.

A shape of the IC package 5 will be described with reference to the coordinate system. As shown in FIG. 3A, the IC package 5 has an approximate square shape viewed from the z-axis direction. As shown in FIG. 3C, the IC package 5 has a plate hexagonal prism shape extending in the y-axis direction viewed from the x-axis direction. Further, a part of the IC package 5 on the first end side of the y-axis has a mirror image of a part of the IC package 5 on the second end side of the y-axis.

That is, a first end surface Xa and a second end surface Xb in the x-axis direction have hexagonal shapes, which have relatively large widths in the y-axis direction. The first end side of the first end surface Xa and the second end side of the first end surface Xa have mirror images in the y-axis. Similarly, the first end side of the second end surface Xb and the second end side of the second end surface Xb have mirror images in the y-axis. Hereinafter, the first end surface Xa is also referred to as a front end surface Xa, and the second end surface Xb is also referred to as a tail end surface Xb. Further, as shown in FIG. 3A, a first end surface Za in the z-axis direction has a square shape that is perpendicular to the z-axis, and a second end surface Zb in the z-axis direction has a quadrangular shape that is perpendicular to the z-axis. The second end surface Zb has a width equal to a width of the first end surface Za in the x-axis direction, and a width smaller than a width of the first end surface Za in the y-axis direction.

Further, as shown in FIGS. 3B and 3C, a first end surface Ya of the IC package 5 in the y-axis direction includes a first perpendicular sub-surface Ya1, and a first inclined sub-surface Ya2. The first perpendicular sub-surface Ya1 is perpendicular to the first end surface Za, and has a relatively large width in the x-axis direction. The first inclined sub-surface Ya2 is connected with the first perpendicular sub-surface Ya1 and the second end surface Zb. Similarly to the first end surface Ya, a second end surface Yb of the IC package 5 in the y-axis direction includes a second perpendicular sub-surface Yb1, and a second inclined sub-surface Yb2.

In the casing 3, the first housing space 9A is defined by the casing 3 to have a shape described later. The shape of the first housing space 9A is defined in order to support the IC package 5 and define a position of the IC package 5 having above-described shape. In the x-axis direction, one end of the first housing space 9A is defined and blocked by an inner wall Xin of the casing 3. Most part of the inner wall Xin of the casing 3 contacts with the front end surface Xa of the IC package 5. That is, most part of the inner wall Xin defines a sub contact region L0, with which the front end surface Xa of the IC package 5 contacts.

The first housing space 9A has a length slightly larger than a length of the IC package 5 in the y-axis direction. In the y-axis direction, a first end of the first housing space 9A is defined and blocked by an inner wall Yain of the casing 3. A space 11Ya is defined between the inner wall Yain and the first perpendicular sub-surface Ya1, the first inclined sub-surface Ya2. Similarly, a second end of the first housing space 9A is defined and blocked by an inner wall Ybin of the casing 3, and a space 11Yb is defined between the inner wall Ybin and the second perpendicular sub-surface Yb1, the second inclined sub-surface Yb2.

In the z-axis direction, a first end of the first housing space 9A is defined and blocked by an inner wall Zain of the casing 3. The inner wall Zain has a shallow recessed portion 12A, which has a relatively large width in the y-axis direction. Thus, the first end surface Za of the IC package 5 contacts with the inner wall Zain on the first end side and the second end side of the inner wall Zain in the y-axis direction. Thus, a space 11Za is defined by the first end side and the second end side of the inner wall Zain, and a bottom surface of the recessed portion 12A. That is, the inner wall Zain contacts with the first end surface Za of the IC package 5 at two separate sub contact regions L1, and L2. The sub contact region L1 is a region at which the first end side of the first end surface Za contacts with the inner wall Zain. The sub contact region L2 is a region at which the second end side of the first end surface Za contacts with the inner wall Zain.

Similarly, in the z-axis direction, a second end of the first housing space 9A is defined and blocked by an inner wall Zbin of the casing 3. The inner wall Zbin has a shallow recessed portion 12B, which has a relatively large width in the y-axis direction. Thus, the second end surface Zb of the IC package 5 contacts with the inner wall Zbin on the first end side and the second end side of the inner wall Zbin in the y-axis direction. Thus, a space 11Zb is defined by the first end side and the second end side of the inner wall Zbin, and a bottom surface of the recessed portion 12B. That is, the inner wall Zbin contacts with the second end surface Zb of the IC package 5 at two separate sub contact regions L3, and L4. The sub contact region L3 is a region at which the first end side of the second end surface Zb contacts with the inner wall Zbin. The sub contact region L4 is a region at which the second end side of the second end surface Zb contacts with the inner wall Zbin.

The recessed portion 12A has a larger width than the recessed portion 12B in the y-axis direction. Thus, the sub contact regions L3 and L4 are placed between the sub contact regions L1 and L2 in the y-axis direction. The sub contact regions L1 and L3 are apart from each other and define the space 11Ya. The first end side of the IC package 5 in the y-axis direction is sandwiched and supported by the sub contact regions L1 and L3 in the z-axis direction. Similarly, the sub contact regions L2 and L4 are apart from each other and define the space 11Yb. The second end side of the IC package 5 in the y-axis direction is sandwiched and supported by the sub contact regions L2 and L4 in the z-axis direction.

The semiconductor substrate 7 built in the IC package 5 is placed between the sub contact regions L3 and L4 in the y-axis direction. That is, the semiconductor substrate 7 is placed other than a portion sandwiched by the sub contact regions L1 and L3, a portion sandwiched by the sub contact regions L2 and L4.

The lead wires 6A to 6C protrude from the tail end surface Xb, and extend to the first housing space 9A. Further, the lead wires 6A to 6C penetrate the first housing space 9A in the second end side direction of the x-axis, and extend to the second housing space 9B. The lead wires 6A to 6C are welded with the respective first ends of the extension terminals 13A to 13C in the second housing space 9B. Further, a capacitor 14 for noise suppression is coupled between the extension terminals 13A and 13C by soldering. Similarly, a capacitor 14 for noise suppression is coupled between the extension terminals 13B and 13C by soldering. The two capacitors 14 are housed in the second housing space 9B. Then, a potting material such as an epoxy resin is injected to the second housing space 9B, and the capacitors 14 are sealed with the potting material.

Further, the casing 3 has a flange-shaped protruding portion 16 on a predetermined portion of the first part of the outside surface of the casing 3. Specifically, the predetermined portion of the first part of the outside surface of the casing 3 corresponds to the opening portion 10 defined by the second housing space 9B. Hereinafter, outside surface of the casing 3 is also referred to as the outside surface 17. Further, the protruding portion 16 is formed around the housing space 9 extending in a radially outside direction. The protruding portion 16 is welded with the resin mold portion 4. Second ends of the extension terminals 13A to 13C penetrate the second housing space 9B in the second end side direction of the x-axis, and are welded with respective first ends of connector terminals 19A to 19C. A connector 18, coupled to the detection apparatus 1, includes the connector terminals 19A to 19C and a part of the resin mold portion 4.

The resin mold portion 4 is formed by injection molding, and is made of thermoplastics resin such as polyolefin, polyamide, or polyester. A portion of the outside surface 17, which is placed between the resin mold portion 4 and the casing 3, is defined as a boundary region 20. Specifically, the boundary region 20 is disposed on the second end side of the outside surface 17 in the x-axis direction. More specifically, a first end of the boundary region 20 is defined between the welding portion, where the lead wires 6A to 6C and the extension terminals 13A to 13C are welded respectively, and the soldering portions of the capacitors 14 in the x-axis direction. A second end of the boundary region 20 is defined as the protruding portion 16 in the x-axis direction.

Under the above-described configuration, the resin mold portion 4 is formed other than the predetermined portion of the outside surface 17, which corresponds to the sub contact regions L0 to L4. In this embodiment, the contact region includes the sub contact regions L0 to L4. Further, the position of the magnetoelectric transducer is defined by contacting the IC package 5 with the sub contact regions L0 to L4, and forming the resin mold portion 4 on the first part of the outside surface 17 of the casing 3.

The detection apparatus 1 according to the first embodiment includes the IC device 2, and the casing 3. The IC device 2 further includes the IC package 5, in which the magnetoelectric transducer is built in, and lead wires 6A to 6C extended from the IC package 5. The casing 3 defines the housing space 9 for housing the IC device 2. Further, the resin mold portion 4 is formed on the first part of the outside surface 17 of the casing 3 by injection molding. The housing space 9 is defined by the inner walls of the casing 3. The inner walls further define sub contact regions L0 to L4 with which the IC package 5 contacts. The resin mold portion 4 is formed other than the predetermined portion of the outside surface 17, which corresponds to the sub contact regions L0 to L4. The position of the magnetoelectric transducer is defined by contacting the IC package 5 with the sub contact regions L0 to L4, and forming the resin mold portion 4 on the first part of the outside surface 17 of the casing 3.

Under the above-described configuration, when forming the resin mold portion 4 by injection molding, the injection pressure caused by resin injection is not applied to the IC package 5 of the IC device 2, and the position of the magnetoelectric transducer is defined. Thus, when defining the position of the magnetoelectric transducer by forming the resin mold portion 4 in an injection molding manner, a characteristic of an output voltage of the IC device 2 is less likely to fluctuate.

Further, the casing 3 has the flange-shaped protruding portion 16 on another predetermined portion of the outside surface 17. The protruding portion 16 is formed around the housing space 9 extending in the radially outside direction, and is welded with the resin mold portion 4. In a case where a boundary region is formed between the outside surface 17 of the casing 3 and the resin mold portion 4, an extraneous fluid may flow to the boundary region. In consideration of this case, the flange-shaped protruding portion 16 is formed around the housing space 9 on another predetermined portion of the outside surface 17, and is welded with the resin mold portion 4. Under the above-described configuration, a fluid flowing path to the housing space 9 through the boundary region is blocked by the welded portion of the protruding portion 16 and the resin mold portion 4. Thus, an extraneous fluid is less likely to flow to the housing space 9 through the boundary region.

Further, the first end side of the IC package 5 in the y-axis direction is sandwiched and supported by the sub contact regions L1 and L3. The second end side of the IC package 5 in the y-axis direction is sandwiched and supported by the sub contact regions L2 and L4. The semiconductor substrate 7 built in the IC package 5 is placed between the sub contact regions L3 and L4 in the y-axis direction. That is, the semiconductor substrate 7 is placed other than the portion sandwiched by the sub contact regions L1 and L3, the portion sandwiched by the sub contact regions L2 and L4.

Under the above-described configuration, since the IC package 5 is not sandwiched between the sub contact regions L1 and L3, and between the sub contact regions L2 and L4, the characteristic of an output voltage of the IC device 2 is less likely to be affected by a pressure generated by being sandwiched between the sub contact regions L1 and L3, and between the sub contact regions L2 and L4. Thus, the characteristic of an output voltage of the IC device 2 is less likely to be affected, and the position of the magnetoelectric transducer is defined more stably.

The lead wires 6A to 6C are electrically coupled with the extension terminals 13A to 13C, respectively, in the second housing space 9B of the housing space 9. A potting material is injected to the housing space 9. Thus, positions of the extension terminals 13A to 13C are defined.

Further, one of the capacitors 14 is coupled between the extension terminals 13A and 13C, and the other of the capacitors 14 is coupled between the extension terminals 13B and 13C. The two capacitors 14 are sealed with the potting material. Thus, positions of the capacitors 14 are defined.

### Second Embodiment

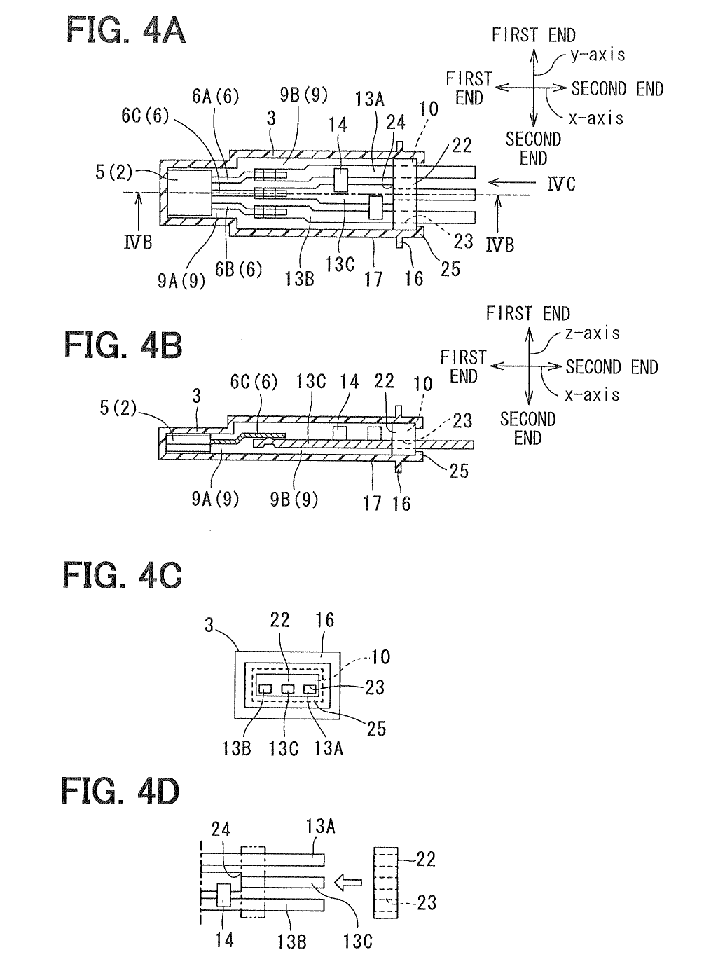

The detection apparatus 1 according to the second embodiment will be described with reference to FIGS. 4A to 4D. In the detection apparatus 1 according to the second embodiment, the opening portion 10 of the casing 3 is covered by the lid 22. The lid 22 may be made of, for example, resin material similar to the resin material of the casing 3. The lid 22 has three through holes 23 corresponding to the extension terminals 13A to 13C. The extension terminals 13A to 13C separately penetrate the respective through holes 23. Further, the extension terminal 13C has the stopper 24 to engage with the lid 22 when the extension terminals 13A to 13C penetrate the through holes 23.

After the lid 22 is engaged with the extension terminal 13C by the stopper 24, the lid 22 is integrated with the casing 3 by thermal caulking to cover the opening portion 10 of the casing 3. The casing 3 has a thermal caulking portion 25 at the second end side of the protruding portion 16 in the x-axis direction. The lid 22 is integrated with the casing 3 by performing thermal caulking at the thermal caulking portion 25. Thus, the positions of the extension terminals 13A to 13C are defined by integrating the lid 22 with the casing 3, without injecting the potting material to the housing space 9.

### Third Embodiment

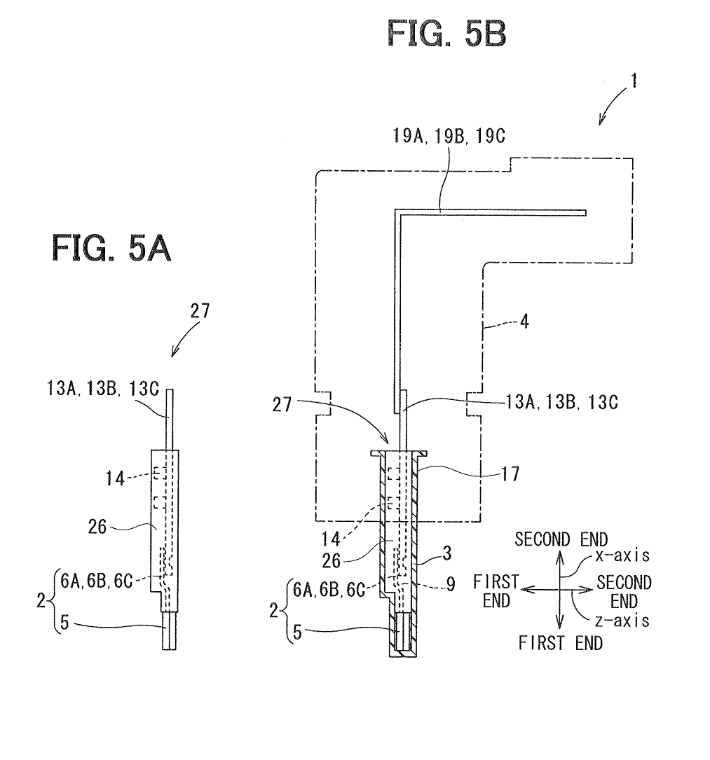

The detection apparatus 1 according to the third embodiment will be described with reference to FIGS. 5A and 5B. The detection apparatus 1 according to the third embodiment includes the sub assembly 27, which includes the insert components 26. The insert components 26 include the IC device 2 other than the IC package 5, the extension terminals 13A to 13C, and the capacitors 14, which are molded integrally by injection molding. The sub assembly 27 is housed in the housing space 9 of the casing 3, and then, the resin mold portion 4 is formed on the first part of the outside surface 17 of the casing 3.

Under the above-described configuration, the positions of the extension terminals 13A to 13C and the positions of the capacitors 14 are preliminarily defined and stabilized in the sub assembly 27. Then, the sub assembly 27 is housed in the casing 3 so that the IC package 5 is contacted with the sub contact regions LO to L4.

Then, the resin mold portion 4 is formed on the first part of the outside surface 17 of the casing 3. Thus, the characteristic of an output voltage of the IC device 2 is less likely to fluctuate, and the extension terminals 13A to 13C and the capacitors 14 are stabilized by preliminarily defining the positions of the extension terminals 13A to 13C and the positions of the capacitors 14.

### Fourth Embodiment

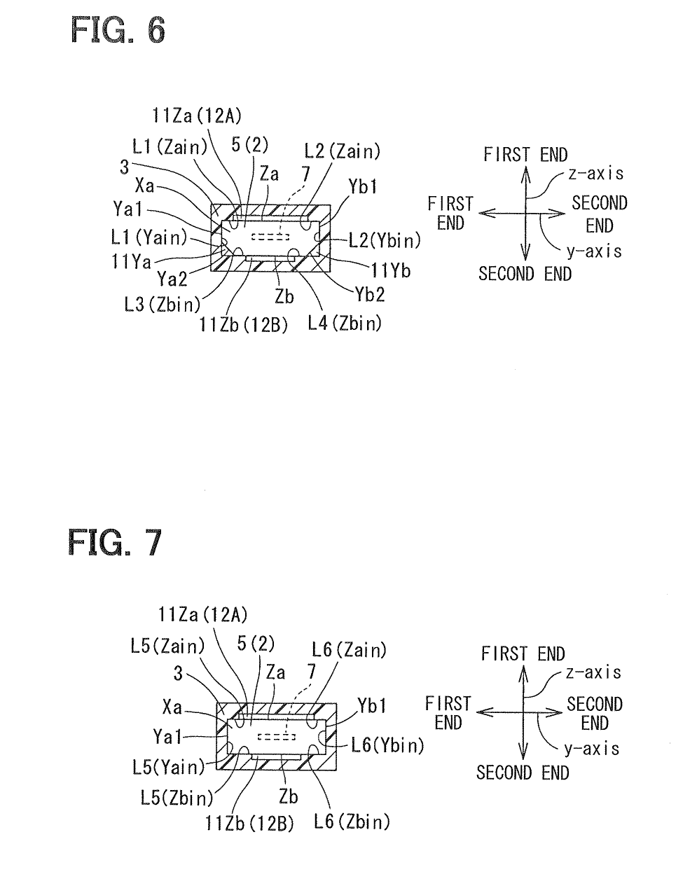

A detection apparatus 1 according to a fourth embodiment will be described with reference to FIG. 6. In the detection apparatus 1 according to the fourth embodiment, the inner wall Yain contacts with the first perpendicular sub-surface Ya1 of the IC package 5. Thus, the sub contact region L1 is enlarged. Specifically, the sub contact region L1 includes a first region contacted with the inner wall Zain, and a second region contacted with the inner wall Yain. Similarly, the inner wall Ybin contacts with the second perpendicular sub-surface Yb1 of the IC package 5. Thus, the sub contact region L2 is enlarged. Specifically, the sub contact region L2 includes a first region contacted with the inner wall Zain, and a second region contacted with the inner wall Ybin. In this embodiment, the contact region includes the sub contact regions L0, L3, L4, and the enlarged sub contact regions L1, L2.

### Fifth Embodiment

A detection apparatus 1 according to a fifth embodiment will be described with reference to FIG. 7. In the detection apparatus 1 according to the fifth embodiment, the first inclined sub-surface Ya2 is not formed on the first end surface Ya of the IC package 5. Thus, the first perpendicular sub-surface Ya1, which is equal to the first end surface Ya, extends to the second end side direction of the z-axis. Thus, the entire inner wall Yain is defined as a sub contact region L5. That is, the detection apparatus 1 according to the fifth embodiment includes the connected sub contact region L5, instead of the separated sub contact regions L1 and L3 described in the first and fourth embodiment. Similarly, the second inclined sub-surface Yb2 is not formed on the second end surface Yb of the IC package 5. Thus, the second perpendicular sub-surface Yb1, which is equal to the first end surface Yb, extends to the second end side direction of the z-axis. Thus, the entire inner wall Ybin is defined as a sub contact region L6. That is, the detection apparatus 1 according to the fifth embodiment includes the connected sub contact region L6, instead of the separated sub contact regions L2 and L4 described in the first and fourth embodiment. Thus, in this embodiment, the contact region includes the sub contact regions L0, L5, L6.

Under the above-described configuration, the first end side of the IC package 5 in the y-axis direction is sandwiched and supported by the sub contact region L5 in the z-axis direction. Similarly, the second end side of the IC package 5 in the y-axis direction is sandwiched and supported by the sub contact region L6 in the z-axis direction.

### Modifications

The configuration of the detection apparatus 1 is not limited to the above-described embodiments. Modifications of the above-described embodiments will be described. In the above-described embodiments, the position of the magnetoelectric transducer is defined by contacting the IC package 5 with the sub contact regions L0 to L4, and forming the resin mold portion 4 on the first part of the outside surface 17 of the casing 3. Alternatively, the position of the magnetoelectric transducer may be defined by only contacting the front end surface Xa of the IC package 5 with the sub contact region L0 of the casing 3, and forming the resin mold portion 4 on the first part of the outside surface 17 of the casing 3. Further, the IC package 5 may be formed to have a different shape, or the contact region is defined differently so that the characteristic of an output voltage of the IC device 2 is less likely to be affected when the IC package 5 is sandwiched by the sub contact regions.

In the above-described embodiments, the IC package 5 has a square plate shape, and the lead wires 6A to 6C are perpendicularly protruded only from the tail end surface Xb, which is connected with one of four end sides of the square. Alternatively, the IC package 5 may have a prism shape, and the lead wires 6A to 6C may be protruded from one or more than one surfaces of the IC package 5 in different directions.

In the above-described embodiments, the second end surface Zb of the IC package has a smaller width in the y-axis direction than the first end surface Za. Alternatively, the second end surface Zb of the IC package may have a larger width in the y-axis direction than the first end surface Za.

In the above-described embodiments, the lead wires 6A to 6C are defined as following. The lead wire 6A is used for outputting a voltage generated by the magnetoelectric transducer, the lead wire 6B is used for providing a power supply to the magnetoelectric transducer, and the lead wire 6C is used for electrically coupling the magnetoelectric transducer to the ground. Alternatively, the lead wires 6A to 6C may be defined in a different manner from the above-described configuration.

### Sixth Embodiment

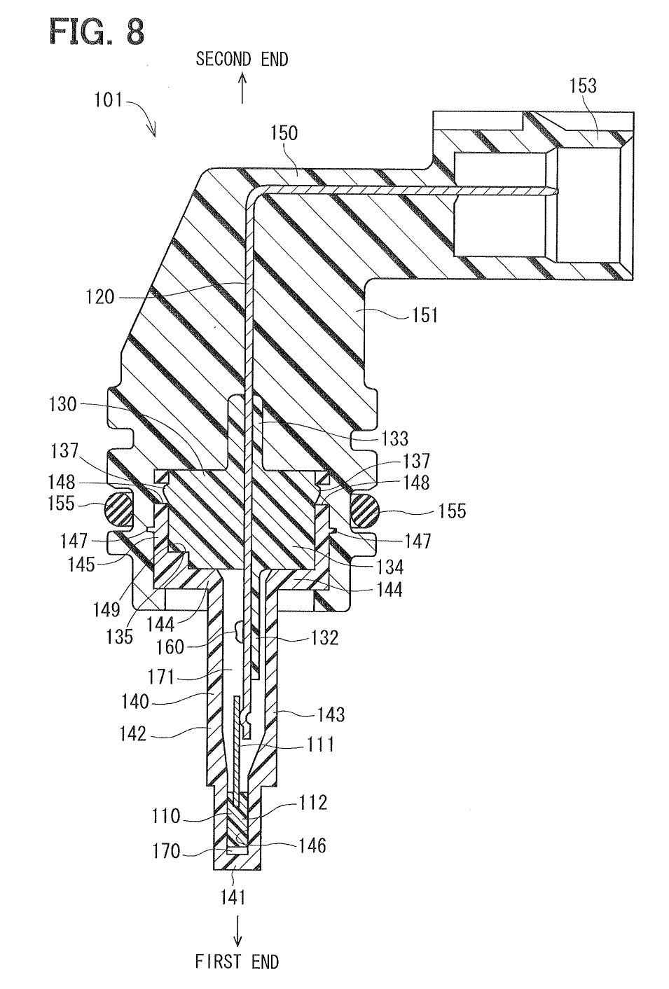

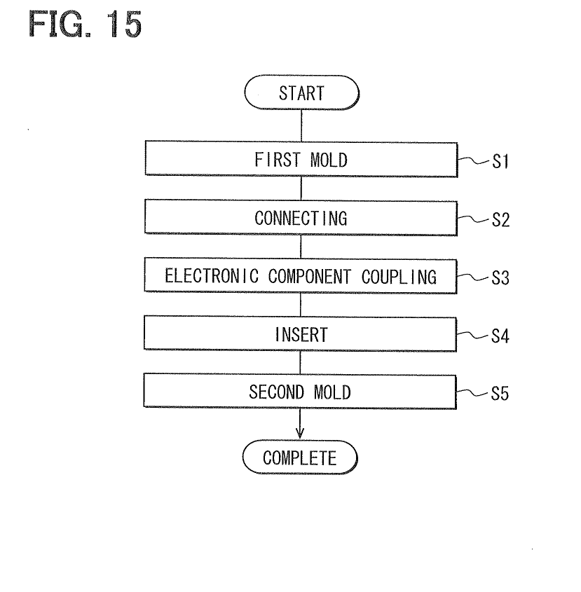

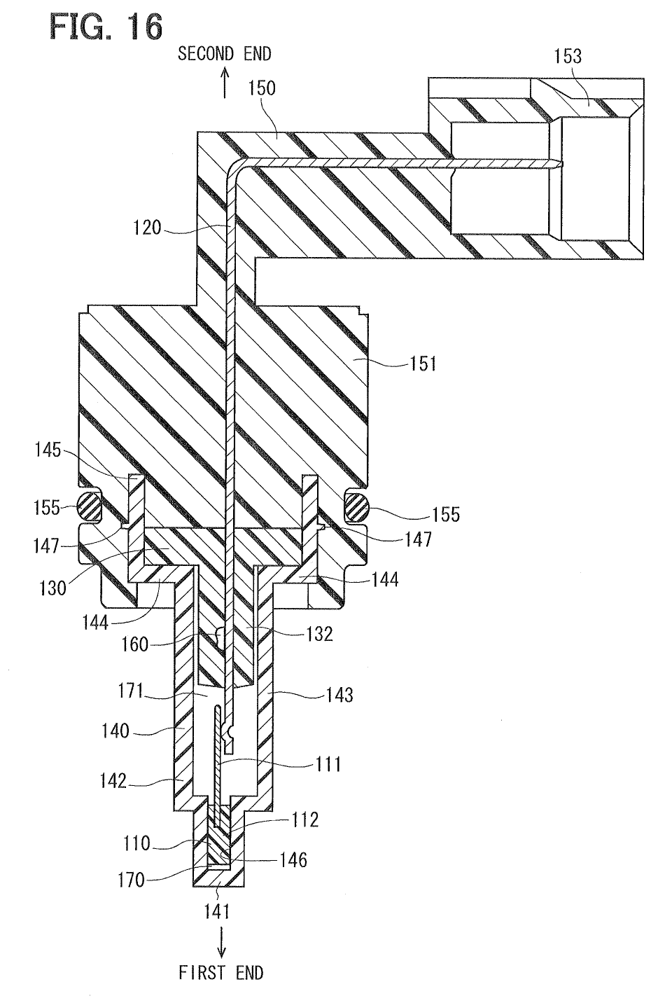

A detection apparatus 101 according to a six embodiment will be described with reference to FIGS. 8 to 15. The detection apparatus 101 according to the sixth embodiment is attached on a transmission of a vehicle (not shown), and is used for detecting a stroke motion. The transmission of the vehicle includes an engagement member, which includes a magnetic circuit. The detection apparatus 101 detects a magnetic field, which changed with a movement of the engagement member. The detection apparatus 101 outputs a signal corresponding to the detected magnetic field to an Electric Control Unit (ECU). The ECU detects a position of the engagement member according to the received signal from the detection apparatus 101.

As shown in FIG. 8, the detection apparatus 101 includes a hall IC device 110 as a detection element, terminals 120, a cover 130, a casing 140, and a housing 150. The hall IC device 110 includes a hall element, an integrated circuit package (IC package), three lead wires 111, and a resin mold portion 112. The hall element and the IC package are not shown in the drawings. The three lead wires 111, and the resin mold portion 112 are shown in FIGS. 8 and 11. The hall element detects a magnetic field according to Hall Effect. The integrated circuit processes a signal output from the hall element. The three lead wires 111 are coupled with the integrated circuit. The resin mold portion 112 molds the hall element, the integrated circuit package, and the three lead wires 111 with resin material. An output voltage of the hall IC device 110 varies according to a magnetic field change.

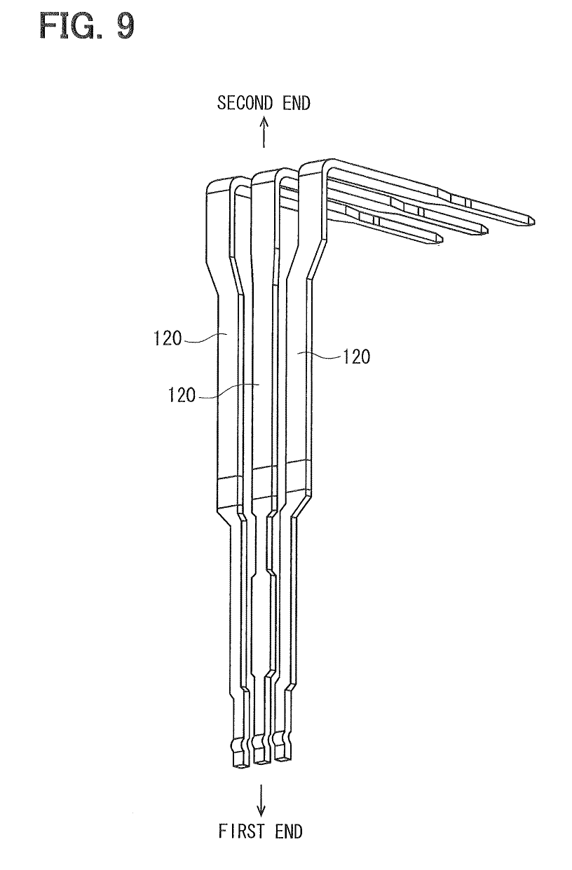

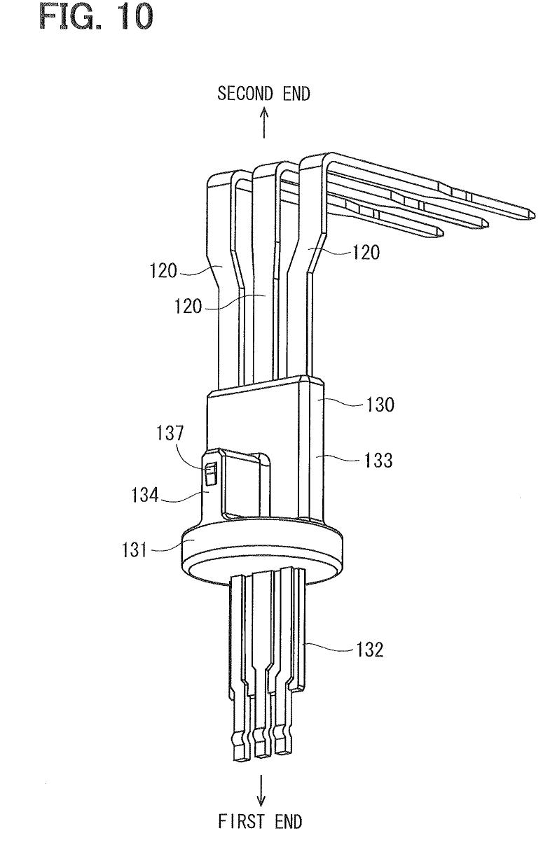

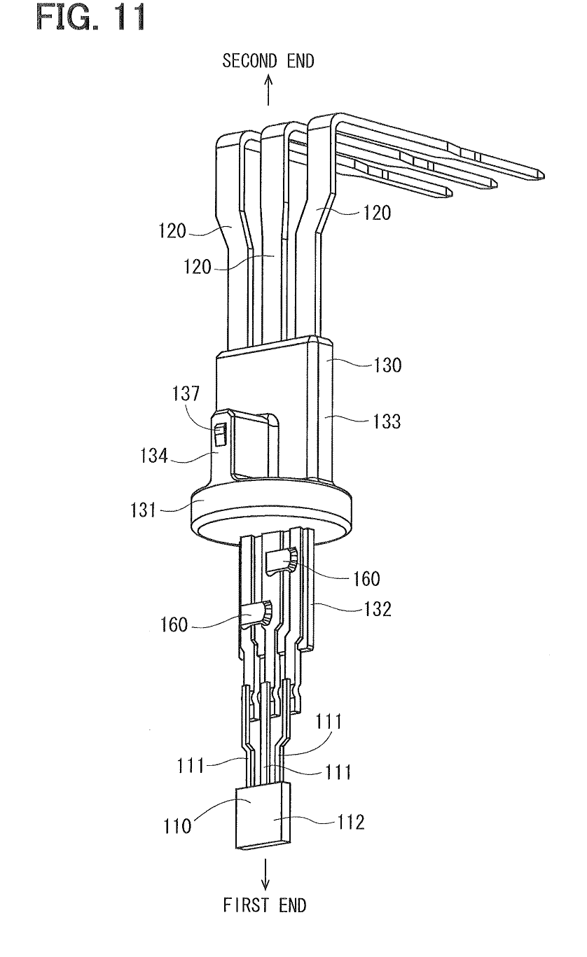

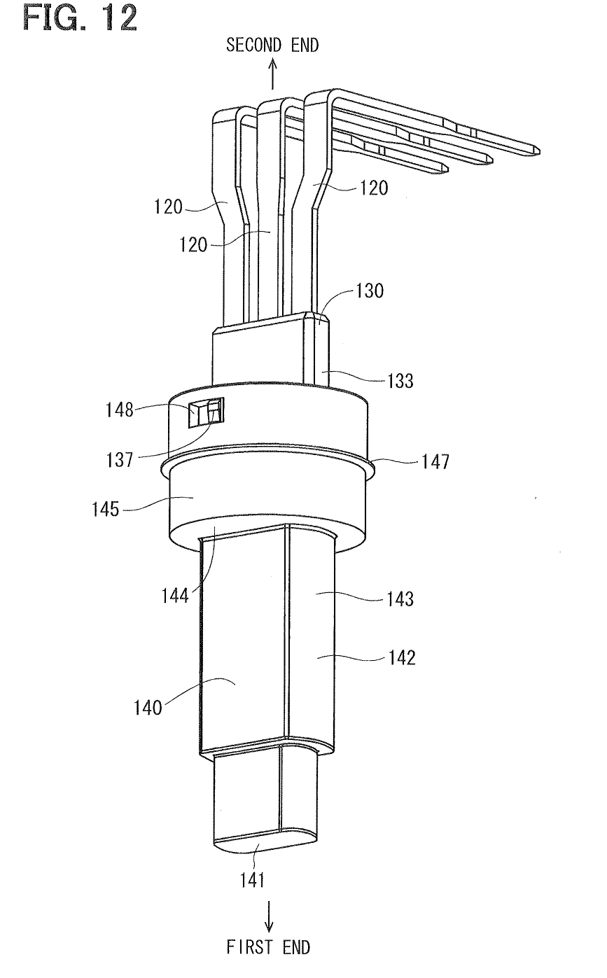

As shown in FIGS. 8 and 9, the three terminals 120 are made of conductive material. A first end of each terminal 120 is coupled with corresponding lead wire 111 of the hall IC device 110 by, for example, welding. A second end of each terminal 120 extends to an outside portion of the casing 140. Hereinafter, an end side, where the hall IC device 110 is placed, is defined as a first end side of the detection apparatus 101. The other end side, which is opposite to the hall IC device 110, is defined as a second end side of the detection apparatus 101. Accordingly, a direction pointing to the first end side is defined as a first end side direction, and a direction pointing to the second end side is defined as a second end side direction. As shown in FIGS. 8 and 10, the cover 130 is made of thermoplastic resin or thermosetting resin, and each of the terminals 120 is partially molded by the cover 130. The cover 130 includes an contact portion 131, an extension portion 132, a protection portion 133, and a fixing portion 134. The contact portion 131 has a disk shape. The extension portion 132 extends in the first end side direction from the contact portion 131 to the hall IC device 110 along the terminals 120. The protection portion 133 extends in the second end side direction from the contact portion 131 to an opposite side of the hall IC device 110 along the terminals 120. The fixing portion 134 is formed approximately perpendicular to the protection portion 133 and the contact portion 131. Each of the terminals 120 is exposed from the extension portion 132 on one broad side in a terminal thickness direction. The terminal thickness direction is defined as a direction, which perpendicularly penetrates from one broad surface to the other broad surface of each of the terminals 120. As shown in FIGS. 8 and 11, the exposed surfaces of the terminals 120 are equipped with two capacitors 160 for noise suppression.

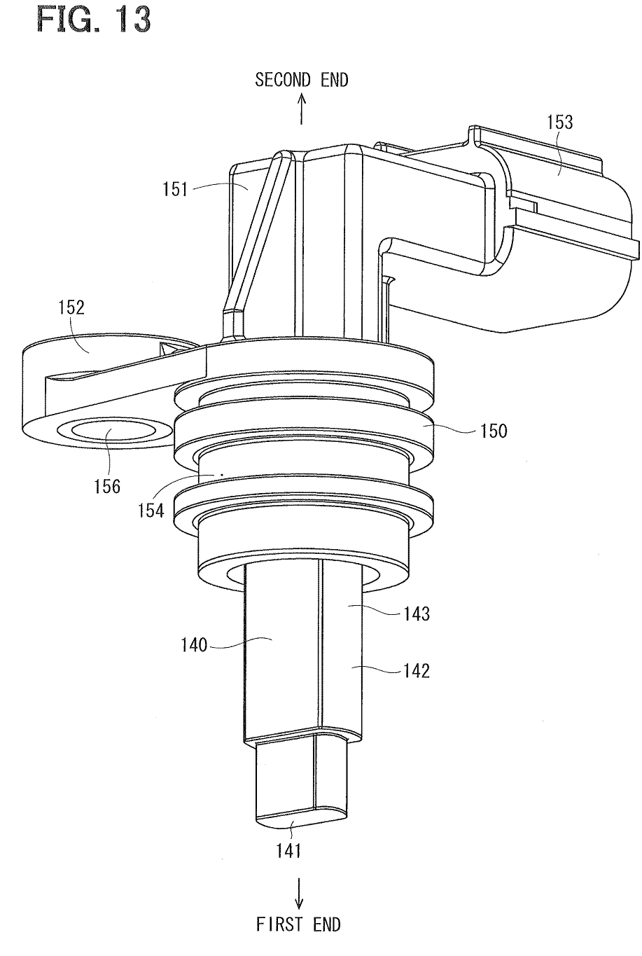

As shown in FIGS. 8 and 12, the casing 140 is made of thermoplastic resin, and includes a bottom portion 141, and a cylindrical portion 142, which extends from an outer edge of the bottom portion 141 in the second end side direction. The cylindrical portion 142 further includes a small diameter portion 143, a step portion 144, and a large diameter portion 145, which are arranged as above-described order in the second end side direction. A housing space 146 for the hall IC device 110 is defined by the small diameter portion 143. A thickness of the hall IC device 110 is approximately equal to an inner width of the housing space 146. A first space 170 is defined between the hall IC device 110 and the bottom portion 141. A second space 171 is defined between the hall IC device 110 and the cover 130. The large diameter portion 145 is disposed on an opposite side of the small diameter portion 143 from the bottom portion 141, and has a larger inner diameter than the small diameter portion 143. The large diameter portion 145 has a protruding portion 147 extending in a radially outside direction around an outside surface of the large diameter portion 145. When forming the housing 150 by injection molding, the protruding portion 147 is melt and integrated with the housing 150.

The contact portion 131 of the cover 130 is inserted to the large diameter portion 145 of the casing 140. The protection portion 133 and the fixing portion 134 may contact with inner walls of the large diameter portion 145. The step portion 144, which connects the small diameter portion 143 and the large diameter portion 145, contacts with a first end surface of the contact portion 131. The first end surface of the contact portion 131 is defined as an end surface of the contact portion 13 disposed on the first end side, and a second end surface of the contact portion 131 is defined as an end surface of the contact portion 13 disposed on the second end side. By this configuration, the casing 140 is covered by the cover 130. On the large diameter portion 145, a through hole 148 is defined in the radial direction. The through hole 148 engages with a stopper 137, which is formed on the fixing portion 134 of the cover 130. The step portion 144 has a protruding portion 149, which is protruded in the second end side direction from the step portion 144. The cover 130 has a recessed portion 135, which is recessed in the second end side direction from an inner bottom surface of the cover 130. The protruding portion 149 of the step portion 144 engages with the recessed portion 135 of the cover 130 so that a position of the cover 130 is defined in a circumferential direction. Thus, the casing 140 is assembled with the cover 130 properly.

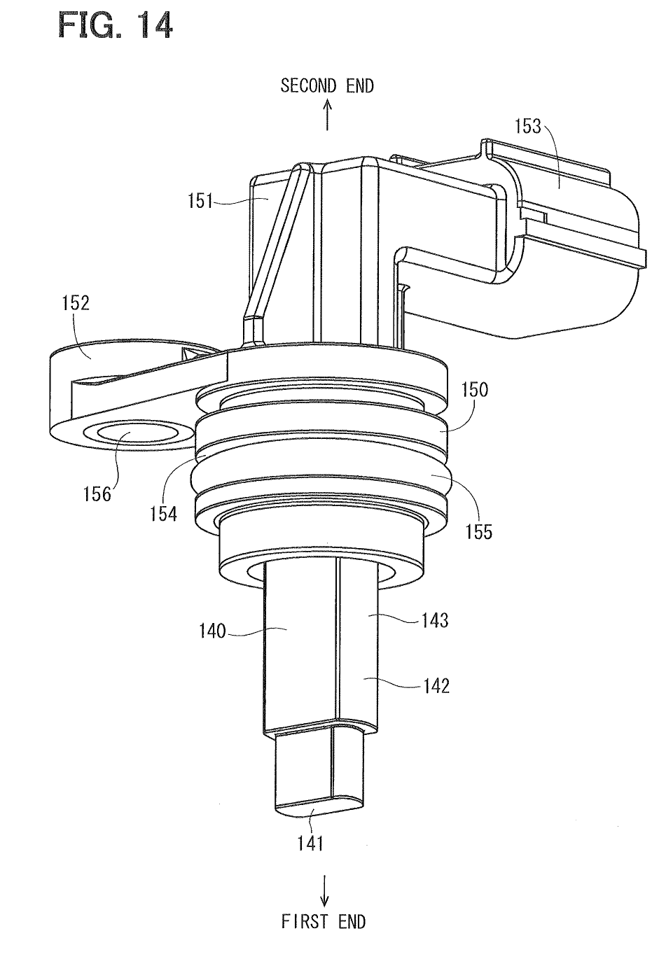

As shown in FIGS. 8 and 13, the housing 150 is made of thermoplastic resin, and includes a body 151, a flange portion 152, and a connector 153. The body 151 is configured by molding the cylindrical portion 142, the large diameter portion 145, the cover 130, and the terminals 120 with resin material. As shown in FIGS. 8 and 14, the body 151 has a recessed portion 154 around an outside surface of the body 151. An O-shape ring member 155 is affixed to the recessed portion 154. The flange portion 152 extends from the body 151 to a radially outside direction. A mounting hole 156 is defined by the flange portion 152, and the mounting hole 156 enables the detection apparatus 101 being mounted on a configuration member of the transmission (not shown). The terminals 120 are exposed outside in an inner space of the connector 153. The connector 153 is fitted with an external terminal (not shown). Thus, the output signal from the hall IC device 110 is transmitted to an in-vehicle ECU via the terminals 120, which are exposed from the connector 153.

A manufacturing method of the detection apparatus 101 will be described with reference to a flowchart shown in FIG. 15 and FIGS. 10 to 14. Hereinafter, an “S” is indicative of step, and “step S1” will be referred to as “S1” for example. As shown in FIG. 10, at S1, as a first mold process, the cover 130 is formed by injection molding with the terminals 120 inserted to the cover 130. At S1, positions of the three terminals 120 are defined. As shown in FIG. 11, at S2, as a connecting process, first ends of the terminals 120 are welded with the lead wires 111 of the hall IC device 110 in order to connect the terminals 120 and the lead wires 111. At S3, as an electronic component coupling process, the capacitors 160 are coupled to the terminals 120 by soldering.

As shown in FIGS. 8 and 12, at S4, as an insert process, the hall IC device 110 is inserted to the housing space 146 of the casing 140. Further, the contact portion 131 of the cover 130 is inserted to the large diameter portion 145 of the casing 140, and the step portion 144 of the casing 140 is contact with the first end surface of the contact portion 131. At this time, the protruding portion 149 of the casing 140 engages with the recessed portion 135 of the cover 130, and the stopper 137 of the cover 130 engages with the through hole 148, which is defined by the large diameter portion 145 of the casing 140. By this configuration, the opening portion of the casing 140 is covered by the cover 130.

As shown in FIGS. 8 and 13, at S5, as a second mold process, the housing 150 is formed by injection molding with the cylindrical portion 142, the cover 130, and the terminals 120 inserted to the housing 150. When performing the injection molding, an injection pressure caused by the resin injection to form the housing 150 is applied to the second end surface of the contact portion 131 of the cover 130. Accordingly, a bottom portion of the contact portion 131, which is placed at the first end side, presses the step portion 144. Thus, the first end surface of the contact portion 131 tightly contacts with the step portion 144 in a moisture-tight manner. Therefore, the above-described configuration suppresses penetration of the resin material of the housing 150 into the casing 140. As shown in FIG. 14, after molding the housing 150, the O-shape ring member 155 is affixed to the body 151. Then, performance check and appearance check are performed, and manufacturing of the detection apparatus 101 is completed.

The detection apparatus 101 according to the sixth embodiment provides following advantages.

(1) In the present embodiment, the cover 130 is formed, and then, the hall IC device 110 is coupled with the terminals 120. When forming the cover 130, an injection pressure is generated by the resin material of the cover 130. Thus, in the first mold process, application of the injection pressure to the hall IC device 110 is suppressed. Therefore, an output reliability of the hall IC device 110 is increased.

(2) In the present embodiment, a penetration of the resin material of the housing 150 to the cylindrical portion 142 is suppressed by the cover 130 in the second mold process. When forming the housing 150, an injection pressure is generated by the resin material of the housing 150. Thus, in the second mold process, application of the injection pressure to the hall IC device 110 is suppressed.

(3) In the present embodiment, the injection pressure caused by the resin injection to form the housing 150 is applied to the contact portion 131 of the cover 130. Accordingly, the contact portion 131 presses the step portion 144 of the casing 140. Thus, the contact portion 131 tightly contacts with the step portion 144 in a moisture-tight manner. Therefore, a penetration of the resin material of the housing 150 to the casing 140 is suppressed with certainty.

(4) In the present embodiment, the first space 170 is defined by the cover 130 and the hall IC device 110, and the second space 171 is defined by the bottom portion 141 and the hall IC device 110. By this configuration, in the insert process and the second mold process, the hall IC device 110 is protected by the first and second spaces 170 and 171, and is not subjected to an external pressure. Thus, an output reliability of the detection element is increased.

(5) In the present embodiment, when forming the housing 150 by injection molding, the protruding portion 147 formed on the outside surface of the casing is melt and integrated with the housing 150. Accordingly, a penetration of moisture to the casing 140 is suppressed.

(6) In the present embodiment, the terminals 120 are molded by the extension portion 132 of the cover 130. Thus, positions of the three terminals 120 are defined, thereby coupling the capacitors 160 to the terminals 120 with ease.

### Seventh Embodiment

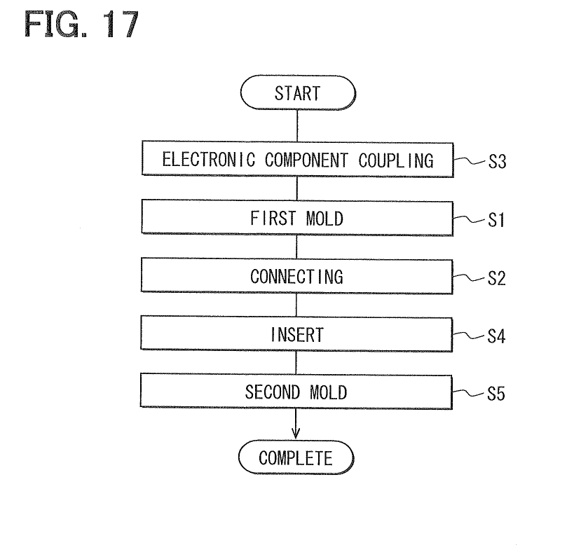

A detection apparatus 101 according to a seventh embodiment will be described with reference to FIGS. 16 and 17. As shown in FIG. 16, in the detection apparatus 101 according to the seventh embodiment, the capacitors 160 are molded by the extension portion 132 of the cover 130. The terminals 120 are exposed from the extension portion 132 on the first end side. A manufacturing method of the detection apparatus 101 according to the seventh embodiment will be described with reference to a flowchart shown in FIG. 17. Firstly, as an electronic component coupling process S3, electronic components such as the capacitors 160 are coupled to the terminals 120. Then, as a first mold process (S1), the cover 130 is formed by injection molding with the terminals 120, and the electronic components such as the capacitors 160 are inserted to the cover 130. Then, S2, S4, and S5, which are similar to the processes described in the sixth embodiment, are performed.

In the detection apparatus 101 according to the seventh embodiment, since the electronic components such as the capacitors 160 are sealed by the cover 130, a penetration of moisture to the capacitors 160 is suppressed. The electronic components may include capacitors, resistors, coils, and IC devices.

### Other Embodiments

In the sixth and seventh embodiments, the detection apparatus is described as being used for detecting a stroke motion. Alternatively, the detection apparatus may be used for detecting various physical quantities such as a temperature, an acceleration, or an angular velocity. For example, when the detection apparatus is used as a temperature detection apparatus, the detection element may be a thermistor. When the detection apparatus is used as a magnetic detection apparatus, the detection element may be a magnetoresistance element. When the detection apparatus is used as an acceleration or angular velocity detection apparatus, the detection element may be a movable member, which moves according to an acceleration or an angular velocity.

While the present disclosure has been described with reference to preferred embodiments thereof, it is to be understood that the disclosure is not limited to the preferred embodiments and constructions. The present disclosure is intended to cover various modifications and equivalent arrangements. In addition, while the various combinations and configurations, which are preferred, other combinations and configurations, including more, less or only a single element, are also within the spirit and scope of the present disclosure.

What is claimed is:

1. A magnetic detection apparatus comprising:
an IC device including an IC package and a plurality of lead wires extended from the IC package, the IC package including a built-in magnetoelectric transducer;
a casing that defines a housing space of the IC device; and
a resin mold portion arranged on a first part of an outside surface of the casing, the first part of the outside surface of the casing corresponding to a first part of an inner wall of the casing,
wherein the housing space is defined by a second part of the inner wall of the casing, the second part of the inner wall of the casing corresponds to a second part of the outside surface of the casing,
wherein a predetermined portion of the second part of the inner wall of the casing is defined as a contact region, which is contacted with a predetermined part of an outside surface of the IC device,
wherein the resin mold portion is arranged other than a predetermined portion of the second part of the outside surface of the casing, which corresponds to the contact region, and
wherein a position of the magnetoelectric transducer is determined by a position of the contact region, with which the IC package contacts, and a position of the resin mold portion.

2. The magnetic detection apparatus according to claim 1, further comprising:
a flange-shaped protruding portion extending in a radially outside direction from a predetermined portion of the first part of the outside surface of the casing, the flange-shaped protruding portion having a ring shape and surrounding the housing space,
wherein the flanged-shaped protruding portion is integrated with the resin mold portion.

3. The magnetic detection apparatus according to claim 1, wherein
the IC package is sandwiched and supported by the contact region.

4. The magnetic detection apparatus according to claim 1, further comprising:
a plurality of extension terminals electrically coupled with the plurality of lead wires, respectively, in the housing space,
wherein the housing space is filled with a potting material.

5. The magnetic detection apparatus according to claim 4, further comprising:
a capacitor coupled between two adjacent extension terminals,
wherein the capacitor is sealed by the potting material in the housing space.

6. The magnetic detection apparatus according to claim 1, further comprising:
a plurality of extension terminals electrically coupled with the plurality of lead wires, respectively, in the housing space,
wherein the casing defines an opening portion in order to accommodate the IC device in the housing space,
wherein the opening portion is covered by a lid, which includes a plurality of through holes,
wherein each extension terminal penetrates the lid via a corresponding through hole,
wherein one of the plurality of extension terminals includes a stopper to engage the plurality of extension terminals with the lid, and
wherein the lid is integrated with the casing by thermal caulking in order to seal the opening portion.

7. The magnetic detection apparatus according to claim 1, further comprising:
a plurality of extension terminals electrically coupled with the plurality of lead wires, respectively, in the housing space; and
one or more capacitors coupled between two adjacent extension terminals,
wherein a part of the IC device other than the IC package, the plurality of extension terminals, and the one or more capacitors provide insert components of a sub assembly, which is injection-molded, and
wherein the resin mold portion is arranged under a condition that the sub assembly is housed in the housing space.

8. A detection apparatus comprising:
a detection element detecting a physical quantity;
a casing including a bottom portion, and a cylindrical portion extending from an outer edge of the bottom portion in one direction, the casing housing the detection element inside of the cylindrical portion on a bottom portion side;
a plurality of terminals, a first end of each terminal coupling with the detection element, and a second end of each terminal extending to an outside of the casing;
a cover covering an opening portion of the cylindrical portion, the cover molding the plurality of terminals, and the opening portion of the cylindrical portion being opposite to the bottom portion of the casing; and
a housing molding the cylindrical portion, the cover, and the plurality of terminals.

9. The detection apparatus according to claim 8, wherein:
the cylindrical portion of the casing includes:
a small diameter portion that defines a housing space of the detection element on the bottom portion side;
a large diameter portion having a larger diameter than the small diameter portion and arranged on an opposite side of the bottom portion; and
a step portion arranged between the small diameter portion and the large diameter portion;
the cover is inserted to an inside of the large diameter portion; and
the cover contacts with the step portion at a surface of the cover, which is arranged on the bottom portion side.

10. The detection apparatus according to claim 8, wherein
the cover and the detection element define a first space in the casing between the cover and the detection element.

11. The detection apparatus according to claim 8, wherein
the bottom portion and the detection element define a second space in the casing between the bottom portion and the detection element.

12. The detection apparatus according to claim 8, wherein:
the casing and the housing are made of thermoplastic resin material;
the housing is an injection molding member; and
the cylindrical portion, the cover, and the plurality of terminals are inserted to the housing.

13. The detection apparatus according to claim 8, further comprising:
an electronic component coupled to the plurality of terminals and molded by the cover.

14. A manufacturing method of the detection apparatus according to claim 8 comprising:
forming the cover by a first injection molding of the plurality of terminals, which are inserted to the cover;
coupling the plurality of terminals with the detection element;
inserting the detection element in the casing after the forming of the cover and the coupling of the plurality of terminals with the detection element;
covering the opening portion of the casing with the cover, which is inserted to the bottom portion side of the cylindrical portion of the casing; and
forming the housing by a second injection molding of the cylindrical portion, the cover, and the plurality of terminals, which are inserted to the housing after the inserting of the detection element in the casing.
